(19) United States
(12) Patent Application Publication
(10) Pub. No.: US 2026/0157102 A1
(43) Pub. Date: Jun. 4, 2026

(54) Display Apparatus

(71) Applicant: LG Display Co., Ltd., Seoul (KR)

(72) Inventors: Dohong Kim, Paju-si (KR); Byeonghun Yu, Paju-si (KR)

(21) Appl. No.: 19/271,516

(22) Filed: Jul. 16, 2025

(30) Foreign Application Priority Data
Dec. 3, 2024 (KR) 10-2024-0178001

(51) Int. Cl. H10K 59/80; H10K 59/131; H10K 59/35

(52) U.S. Cl. CPC H10K 59/8794; H10K 59/131; H10K 59/351; H10K 59/8793

(57) ABSTRACT

A display apparatus comprises: a substrate having a display area in which a plurality of sub-pixels are arranged and a non-display area around the display area; a plurality of lines arranged in the non-display area on the substrate and connected to each of a plurality of tabs; a connecting line connecting the plurality of lines; and a heat path changing portion partially overlapping the connecting line, the substrate includes a cathode electrode arranged in the display area and a portion of the non-display area, the heat path changing portion is connected to the cathode electrode.

### CROSS-REFERENCE TO RELATED APPLICATION

This application claims the benefit of Republic of the Korea Patent Application No. 10-2024-0178001 filed on Dec. 3, 2024, which is hereby incorporated by reference in its entirety.

### BACKGROUND

### Field of Technology

The present disclosure relates to a display apparatus displaying images.

### Discussion of the Related Art

Since an organic light emitting display apparatus has a high response speed and low power consumption and self-emits light without requiring a separate light source unlike a liquid crystal display apparatus, there is no problem in a viewing angle and thus the organic light emitting display apparatus has received attention as a next-generation flat panel display apparatus.

Such a display apparatus displays an image through light emission from a light-emitting element layer including a light-emitting layer interposed between a pixel electrode and an opposing electrode.

Meanwhile, the display apparatus includes a plurality of tabs that apply a power (or a signal) to the light-emitting element layer for displaying the image, and a plurality of lines connected to each of the plurality of tabs. However, if there is a power (or a signal) deviation between the lines connected to different tabs, a connecting line (e.g., a shorting bar) connecting the plurality of lines will become heated (or overheated). Heating (or overheating) of the connecting line (e.g., the shorting bar) can cause problems such as melting of a polarizing plate.

### SUMMARY

An embodiment of the present disclosure is to provide a display apparatus capable of preventing or at least reducing a likelihood of melting of a polarizing plate.

Further, an embodiment of the present disclosure is to provide a display apparatus in which the peak temperature of a display panel can be reduced.

Further, an embodiment of the present disclosure is to provide a display apparatus capable of preventing a vertical line staining.

Further, an embodiment of the present disclosure is to provide a display apparatus whose power consumption can be reduced.

The problems to be solved by the examples of the present disclosure are not limited to those mentioned above, and other problems not mentioned will be apparent to one of ordinary skill in the art to which the technical spirits of the present disclosure belong from the following description.

A display apparatus comprising: a substrate having a display area in which a plurality of sub-pixels are arranged and a non-display area around the display area; a plurality of lines arranged in the non-display area on the substrate and connected to each of a plurality of tabs; a connecting line connecting the plurality of lines; and a heat path changing portion partially overlapping the connecting line, the substrate includes a cathode electrode arranged in the display area and a portion of the non-display area, the heat path changing portion is connected to the cathode electrode.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a schematic plan view of a display apparatus according to one embodiment of the present disclosure.

FIG. 2 is a schematic cross-sectional view of the line I-I′ shown in FIG. 1 according to one embodiment of the present disclosure.

FIG. 3 is a schematic plan view of part A shown in FIG. 1 according to one embodiment of the present disclosure.

FIG. 4 is a schematic enlarged view of part B shown in FIG. 3 according to one embodiment of the present disclosure.

FIG. 5 is a schematic cross-sectional view of the line II-II′ shown in FIG. 4 according to one embodiment of the present disclosure.

FIG. 6 is a schematic enlarged view of part C shown in FIG. 4 according to one embodiment of the present disclosure.

FIG. 7 is a schematic cross-sectional view of the line III-III′ shown in FIG. 4 according to one embodiment of the present disclosure.

### DETAILED DESCRIPTION

Reference will now be made in detail to the embodiments of the present disclosure, examples of which are illustrated in the accompanying drawings. Wherever possible, the same reference numbers will be used throughout the drawings to refer to the same or like parts.

Advantages and features of the present disclosure, and implementation methods thereof will be clarified through following embodiments described with reference to the accompanying drawings.

The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art.

A shape, a size, a ratio, an angle, and a number disclosed in the drawings for describing embodiments of the present disclosure are merely one example, and thus, the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted.

In a case where ‘comprise’, ‘have’, and ‘include’ described in the present disclosure are used, another part may be added unless ‘only˜’ is used. The terms of a singular form may include plural forms unless referred to the contrary.

In construing an element, the element is construed as including an error range although there is no explicit description.

In describing a position relationship, for example, when a position relation between two parts is described as ‘on˜’, ‘over˜’, ‘under˜’, and ‘next˜’, one or more other parts may be disposed between the two parts unless ‘just’ or ‘direct’ is used.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc. may be used herein to describe various elements, these elements should not be limited by these terms.

These terms are only used to distinguish one element from another. For example, a first element could be termed a second element, and, similarly, a second element could be termed a first element, without departing from the scope of the present disclosure.

“X-axis direction”, “Y-axis direction” and “Z-axis direction” should not be construed by a geometric relation only of a mutual vertical relation and may have broader directionality within the range that elements of the present disclosure may act functionally.

The term “at least one” should be understood as including any and all combinations of one or more of the associated listed items. For example, the meaning of “at least one of a first item, a second item and a third item” denotes the combination of all items proposed from two or more of the first item, the second item and the third item as well as the first item, the second item or the third item.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in co-dependent relationship.

Hereinafter, the preferred embodiments of the present disclosure will be described in detail with reference to the accompanying drawings.

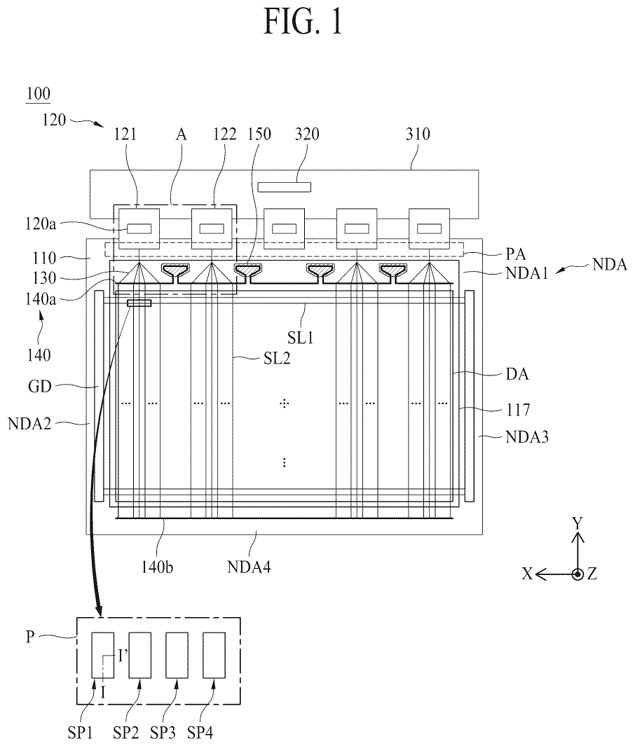

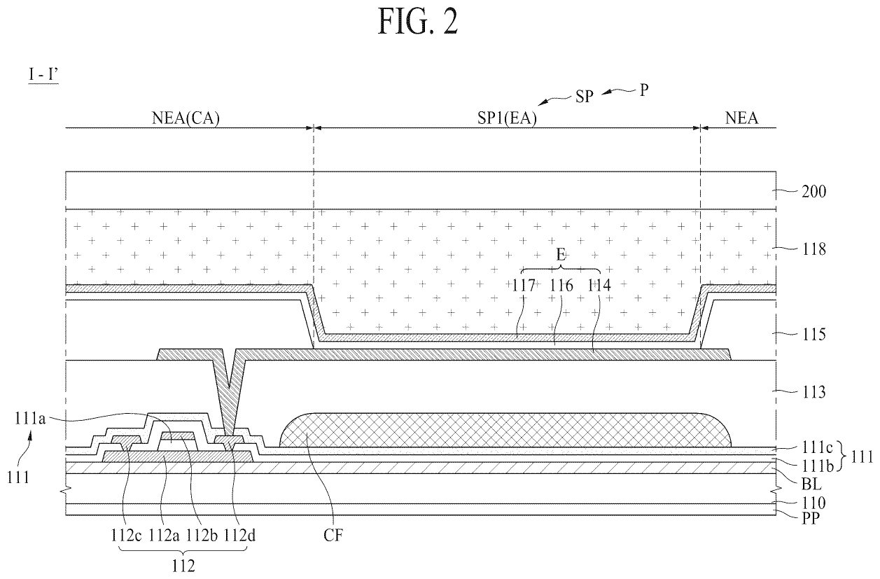

FIG. 1 is a schematic plan view of a display apparatus according to one embodiment of the present disclosure and FIG. 2 is a schematic cross-sectional view of the line I-I′ shown in FIG. 1 according to one embodiment of the present disclosure.

Hereinafter, a first direction (Y-axis direction) represents a direction parallel to a plurality of second signal lines SL2 arranged vertically, a second direction (X-axis direction) represents a direction parallel to a plurality of first signal lines SL1 arranged horizontally, and a third direction (Z-axis direction) represents a thickness direction of a display apparatus 100.

The following description will be based on that the display apparatus 100 according to one embodiment of the present disclosure is an organic light emitting display apparatus, but is not limited thereto. That is, the display apparatus according to one embodiment of the present disclosure may be implemented as any one of a liquid crystal display apparatus, a field emission display apparatus, a quantum dot lighting emitting diode apparatus, and an electrophoretic display apparatus as well as the organic light emitting display apparatus.

Referring to FIG. 1, the display apparatus 100 according to one embodiment of the present disclosure may include a substrate 110, a plurality of tabs 120, a plurality of lines 130, a connecting line 140, and a heat path changing portion 150. The tabs 120 apply a power (or a signal) to a light-emitting element layer for displaying an image.

The substrate 110 may include a display area DA in which a plurality of subpixels SP are arranged and a non-display area NDA around the display area DA. As shown in FIG. 1, the substrate 110 may further include a cathode electrode 117 disposed in a portion of the non-display area NDA and the display area DA (or an entire display area DA).

The plurality of tabs 120 may be coupled to one side of the substrate 110. For example, the plurality of tabs 120 may be coupled to an upper side of the substrate 110 that is partially connected to a circuit board 310. The plurality of lines 130 may be connected to each of the plurality of tabs 120. According to one example, the plurality of lines 130 may be placed in the non-display area NDA on the substrate 110. The connecting line 140 (or a plurality of connecting lines 140) may connect the plurality of lines 130. For example, as shown in FIG. 1, the connecting line 140 (or each of the plurality of connecting lines 140) may be arranged in the second direction (X-axis direction) along one side (or one side of the substrate 110 arranged in the second direction (X-axis direction)) of the substrate 110 and connected to each of the plurality of lines 130. In one example, the connecting line 140 may be a pixel power shorting bar.

As shown in FIG. 1, the connecting line 140 may include an upper connecting line 140a positioned in an upper non-display area (or a first non-display area NDA1) based on the display area DA, and a lower connecting line 140b positioned in a lower non-display area (or a fourth non-display area NDA4) based on the display area DA. Each of the upper connecting line 140a and the lower connecting line 140b can be extended in the second direction (X-axis direction). As shown in FIG. 1, the upper connecting line 140a and the lower connecting line 140b can be arranged in parallel with the display area DA interposed therebetween.

The second signal lines SL2 arranged in the display area DA can extend in the first direction (Y-axis direction) and be connected to each of the upper connecting line 140a and the lower connecting line 140b. Accordingly, the second signal lines SL2 can receive power (or a signal) for driving the pixel P from the connecting line 140.

The heat path changing portion 150 may partially overlap with the connecting line 140. For example, the heat path changing portion 150 may overlap with a part of the connecting line 140 in the non-display area NDA. Accordingly, the heat path changing portion 150 may change a path along which heat generated in the connecting line 140 progresses. For example, the heat path changing portion 150 can be placed between a connecting line 140 and a polarizing plate PP (shown in FIG. 2) to change the path of heat traveling from the connecting line 140 to the polarizing plate PP.

The heat path changing portion 150 can be connected to the cathode electrode 117. Therefore, the heat path changing portion 150 can change the path of heat generated from the connecting line 140 and traveling to the polarizing plate PP to the cathode electrode 117. Accordingly, the display apparatus 100 according to one embodiment of the present disclosure is equipped to dissipate (or disperse) heat generated from the connecting line 140 through the cathode electrode 117, thereby preventing or at least reducing a likelihood of melting of the polarizing plate PP.

Referring to FIG. 1, the display apparatus 100 according to one embodiment of the present disclosure may include a display panel having a gate driver GD, a plurality of tabs 120 including a source drive integrated circuit (hereinafter, referred to as “IC”) 120a, a circuit board 310, and a timing controller 320.

The substrate 110 may include a thin film transistor 112, and may be a transistor array substrate, a lower substrate, a base substrate, or a first substrate. The substrate 110 may be a transparent glass substrate or a transparent plastic substrate.

The opposite substrate 200 may be bonded to the substrate 110 via an adhesive member. For example, the opposing substrate 200 has a smaller size than the substrate 110 and can be bonded to the remaining portion of the substrate 110 except for the pad portion. The opposite substrate 200 may be an upper substrate, a second substrate, or an encapsulation substrate.

The gate driver GD supplies gate signals to the gate lines in accordance with the gate control signal input from the timing controller 320. When the source drive IC 120a is manufactured as a driving chip, the source drive IC 120a may be packaged in the plurality of tabs 120 in a chip on film (COF) method or a chip on plastic (COP) method.

Pads such as power pads and data pads may be formed in a non-display area of a display panel. The plurality of tabs 120 may include lines connecting the pads to a source drive IC 120a and lines connecting the pads to lines of a circuit board 310. The plurality of tabs 120 may be attached to the pads by using an anisotropic conducting film, whereby the pads may be connected to the lines of the plurality of tabs 120. Meanwhile, as shown in FIG. 1, the plurality of lines 130 can be connected to each of the plurality of tabs 120.

Referring to FIG. 1, the substrate 110 according to one example may include a display area DA and a non-display area NDA.

The display area DA is an area where an image is displayed, and may be a pixel array area, an active area, a pixel array unit, a display unit, or a screen. For example, the display area DA may be disposed at a central portion of the display panel.

The display area DA according to one example may include gate lines, data lines, pixel power lines, and a plurality of pixels P. Each of the plurality of pixels P may include a plurality of sub-pixels SP that may be defined by the gate lines and the data lines. Each of the plurality of sub-pixels SP may be defined as a minimum unit area in which light is actually emitted.

According to one example, at least four sub-pixels, which are provided to emit light of different colors and disposed to be adjacent to one another, among the plurality of sub-pixels SP constitute one unit pixel P. One unit pixel may include, but is not limited to, a red sub-pixel, a green sub-pixel, a blue sub-pixel, a white sub-pixel. According to another example, three sub-pixels SP, which are provided to emit light of different colors and disposed to be adjacent to one another, among the plurality of sub-pixels SP constitute one unit pixel. One unit pixel may include at least one red sub-pixel, at least one green sub-pixel, at least one blue sub-pixel, but is not limited thereto.

Each of the plurality of sub-pixels SP may include a thin film transistor 112 and a light emitting element connected to the thin film transistor 112. The sub-pixel may include a light emitting layer (or an organic light emitting layer) interposed between a first electrode and a second electrode.

The organic light emitting layer disposed in each of the plurality of sub-pixels SP may individually emit light of different colors or may commonly emit white light. According to one example, when the organic light emitting layer of each of the plurality of sub-pixels SP commonly emits white light, each of the red sub-pixel, the green sub-pixel and the blue sub-pixel may include a color filter (shown in FIG. 2) (or a wavelength conversion member) for converting the white light into light of different colors. In this case, the white sub-pixel according to one example may not include a color filter. The color filter CF, according to one example, can include a green color filter, a red color filter, and a blue color filter.

In the display apparatus 100 according to one embodiment of the present disclosure, an area in which a red color filter is provided may be a red sub-pixel SP1, an area in which a blue color filter is provided may be a blue sub-pixel SP3, an area in which a green color filter is provided may be a green sub-pixel SP4, and an area in which a color filter is not provided may be a white sub-pixel SP2. In the present disclosure, the red sub-pixel may be expressed as a first sub-pixel SP1 provided to emit red light, the blue sub-pixel may be expressed as a third sub-pixel SP3 configured to emit blue light, the green sub-pixel may be expressed as a fourth sub-pixel SP4 provided to emit green light, and the white sub-pixel may be represented as a second sub-pixel SP2 provided to emit white light.

Each of the plurality of sub-pixels SP supplies a predetermined current to the organic light emitting element in accordance with a data voltage of the data line when a gate signal is input from the gate line by using the thin film transistor 112. For this reason, the light emitting layer of each of the sub-pixels may emit light with a predetermined brightness in accordance with the predetermined current.

Referring to FIG. 2, the display area DA includes a light emission area EA and a non-light emission area NEA. The light emission area EA is an area where light is emitted by a light emitting element layer E. The non-light emission area NEA is an area that does not transmit most of light incident from the outside. For example, the non-light emission area NEA can be an area other than the light emission area EA from which light is emitted. In one example, the non-light emission area NEA can be provided on the substrate 110 between the plurality of sub-pixels SP. A circuit area CA for emitting light from the light-emitting element layer 120 may be placed in the non-light emission area NEA. As shown in FIG. 2, the circuit area CA according to one example may be placed below a bank 115.

In the non-light emission area NEA, the plurality of pixels P and a plurality of lines for driving each of the plurality of pixels P can be disposed. The plurality of lines, according to one example, can include a plurality of first signal lines SL1 and a plurality of second signal lines SL2.

The plurality of first signal lines SL1 may be extended in the second direction (X-axis direction). Each of the plurality of first signal lines SL1 may include at least one gate line (or scan line).

Hereinafter, when the first signal line includes a plurality of lines, one first signal line may refer to a signal line group comprised of a plurality of lines. For example, when the first signal line includes two scan lines, one first signal line may refer to a signal line group comprised of two scan lines.

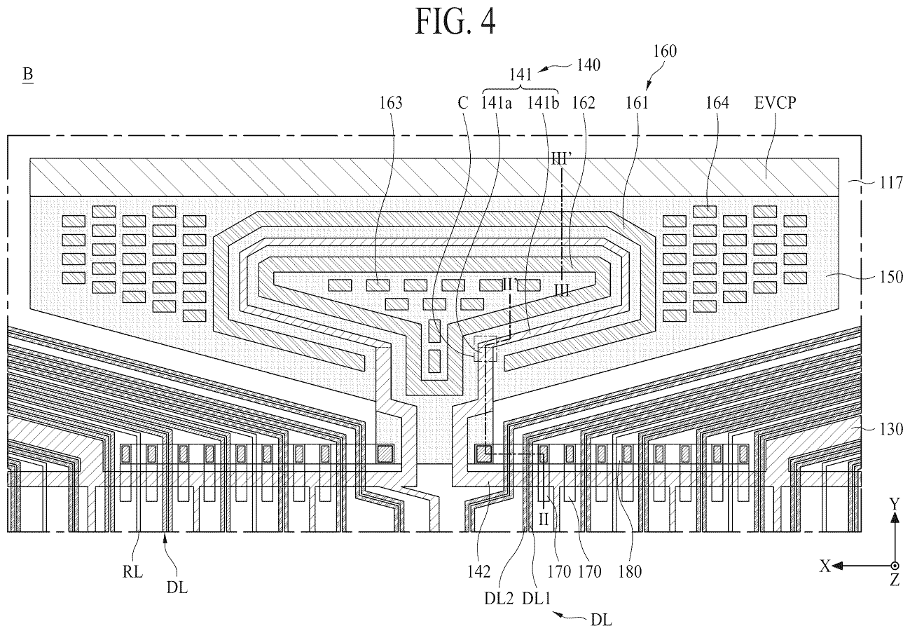

The plurality of second signal lines SL2 can extend in the first direction (Y-axis direction). The plurality of second signal lines SL2 may be lines extended from the plurality of lines 130. The plurality of second signal lines SL2 can intersect with the plurality of first signal lines SL1. Each of the plurality of second signal lines SL2 can include a pixel power line, and a common power line disposed spaced apart from the pixel power line. In an embodiment, the plurality of second signal lines SL2 can further include a plurality of data lines DL (shown in FIG. 4), and a reference line RL (shown in FIG. 4). The plurality of data lines DL are provided to supply driving signals to each of the plurality of sub-pixels. For example, the plurality of data lines DL can include a first data line DL1 for driving the first sub-pixel SP1, a second data line DL2 for driving the second sub-pixel SP2, a third data line DL3 for driving the third sub-pixel SP3, and a fourth data line DL4 for driving the fourth sub-pixel SP4.

Hereinafter, when the second signal line includes a plurality of lines, one second signal line may refer to a signal line group comprised of a plurality of lines. For example, when the second signal line includes four data lines, a pixel power line, a common power line and a reference line, one second signal line may refer to a signal line group comprised of four data lines, a pixel power line, a common power line and a reference line.

Referring back to FIG. 1, the non-display area NDA is an area on which an image is not displayed, and may be a peripheral circuit area, a signal supply area, an inactive area or a bezel area. The non-display area NDA may be configured to be in the vicinity of the display area DA. That is, the non-display area NDA may be disposed to surround the display area DA.

The display apparatus 100 according to one embodiment of the present disclosure can include a pad portion PA disposed in the non-display area NDA. The pad portion PA can be for driving the plurality of pixels P. For example, the pad portion PA can supply power and/or signals for the plurality of pixels P disposed in the display area DA to output images. According to one example, the pad portion PA may be placed in the non-display area NDA (or the first non-display area NDA1) above the display area DA based on FIG. 1.

The gate driver GD supplies gate signals to the gate lines in accordance with the gate control signal input from the timing controller 320. The gate driver GD may be formed on one side of the display area DA of the display panel or on the non-display area NDA outside both sides of the display area DA in a gate driver in panel (GIP) method as shown in FIG. 1.

The plurality of gate drivers GD may be separately disposed on a left side of the display area DA, that is, the second non-display area and a right side of the display area DA, that is, the third non-display area. According to one example, the plurality of gate drivers GD may be connected to the plurality of pixels P and the plurality of first signal lines SL1 for supplying signals to the plurality of pixels P. The plurality of first signal lines SL1 may include at least one signal line for supplying a signal for driving the pixel P.

The plurality of second signal lines SL2 may be extended in the first direction (Y-axis direction). The plurality of second signal lines SL2 may cross the plurality of first signal lines SL1. The plurality of second signal lines SL2 may include a pixel power line and at least one data line to supply a data voltage to the pixel P. Each of the plurality of second signal lines SL2 may be connected to at least one of a plurality of pads, a pixel power shorting bar or a common power shorting bar. The pixel power shorting bar can be placed in the first non-display area NDA1 located above the display area DA and in the fourth non-display area NDA4 located below it.

The pixels are provided to overlap at least one of the first signal line or the second signal line and emit predetermined light to display an image. The light emission area EA may correspond to an area, which emits light, in the pixel P.

Referring to FIG. 2, the non-light emission area NEA may refer to an area that is provided in the display area DA and does not emit light and may be expressed as a dead zone because it does not emit light. The dead zone according to one example may be an area in which a bank is provided, but is not limited thereto, and may refer to an area in which light is not emitted.

Hereinafter, with reference to FIG. 2, the structure of each of the plurality of sub-pixels SPs will be described in detail.

Referring to FIG. 2, the display apparatus 100 according to one embodiment of the present disclosure can include a buffer layer BL, a circuit element layer 111, a thin film transistor 112, a color filter CF, a planarization layer 113, an anode electrode 114, a bank 115, an organic light emitting layer 116, a cathode electrode 117, and an encapsulation layer 118.

As shown in FIG. 2, the polarizing plate PP may be placed at a bottom of the substrate 110. According to one example, the polarizing plate PP is intended to reduce external light reflectance due to the plurality of lines.

Each of the subpixels SP according to one embodiment may include a circuit element layer 111 provided on an upper surface of the buffer layer BL, including a gate insulating layer 111a, an interlayer insulating layer 111b, and a passivation layer 111c, a color filter CF provided on the circuit element layer 111, a planarization layer 113 provided on the color filter CF.

Also, each of the subpixels SP may further include an anode electrode 114 provided on the planarization layer 113, a bank 115 covering one edge of the anode electrode 114, an organic light-emitting layer 116 on the anode electrode 114 and the bank 115, a cathode electrode 117 on the organic light-emitting layer 116, and an encapsulation layer 118 on the cathode electrode 117.

The thin film transistor 112 for driving the subpixel SP may be disposed on the circuit element layer 111. The buffer layer BL may be included in the circuit element layer 111 together with the gate insulating layer 111a, the interlayer insulating layer 111b, and the passivation layer 111c. The anode electrode 114, the organic light emitting layer 116 and the cathode electrode 117 may be included in the light emitting element layer E.

The buffer layer BL may be formed between the substrate 110 and the gate insulating layer 111a to protect the thin film transistor 112. The buffer layer BL may be disposed on the entire surface (or front surface) of the substrate 110. The buffer layer BL may serve to block diffusion of a material contained in the substrate 110 into a transistor layer during a high temperature process of a manufacturing process of the thin film transistor 112.

The thin film transistor 112 (or a drive transistor) according to an example may include an active layer 112a, a gate electrode 112b, a source electrode 112c, and a drain electrode 112d.

The active layer 112a may include a channel area, a drain area and a source area, which are formed in a thin film transistor area of a circuit area CA of the subpixel SP. The drain area and the source area may be spaced apart from each other with the channel area interposed therebetween.

The active layer 112a may be formed of a semiconductor material based on any one of amorphous silicon, polycrystalline silicon, oxide and organic material.

The gate insulating layer 111a may be formed on the channel area of the active layer 112a. As an example, the gate insulating layer 111a may be formed in an island shape only on the channel area of the active layer 112a.

The gate electrode 112b may be formed on the gate insulating layer 111a to overlap the channel area of the active layer 112a.

The interlayer insulating layer 111b can be formed to partially overlap the gate electrode 112b and the drain area and source area of the active layer 112a. The interlayer insulating layer 111b may be formed over the entire light emission area where light is emitted, as in FIG. 2, in the circuit area CA and the subpixel SP.

The source electrode 112c may be electrically connected to the source area of the active layer 112a through a source contact hole provided in the interlayer insulating layer overlapped with the source area of the active layer 112a. The drain electrode 112d may be electrically connected to the drain area of the active layer 112a through a drain contact hole provided in the interlayer insulating layer overlapped with the drain area of the active layer 112a.

The drain electrode 112d and the source electrode 112c may be made of the same metal material. For example, each of the drain electrode 112d and the source electrode 112c may be made of a single metal layer, a single layer of an alloy or a multi-layer of two or more layers, which is the same as or different from that of the gate electrode 112b.

The passivation layer 111c may be provided on the substrate 110 to cover the pixel area. The passivation layer 111c covers a drain electrode 112d, a source electrode 112c and a gate electrode 112b of the thin film transistor 112, and the buffer layer BL.

The color filter CF may be placed on the passivation layer 111c. For example, the color filter CF may be placed between the circuit element layer 111 and the planarization layer 113. The color filter CF may include the green color filter arranged in the green subpixel, the red color filter arranged in the red subpixel, and the blue color filter arranged in the blue subpixel. Since the white subpixel is provided to emit white light, it may not include the color filter.

The planarization layer 113 may be provided on the substrate 110 to cover the passivation layer 111c and the color filter CF. According to one example, the planarization layer 113 may be placed between the substrate 110 and the anode electrode 114. The planarization layer 113 may be formed in the entire circuit area CA in which the thin film transistor 112 is disposed and the entire light emission area EA. In addition, the planarization layer 113 may be formed in the other non-display area NDA except a pad portion PA of the non-display area NDA and the entire display area DA. For example, the planarization layer 113 may include an extension portion (or an enlarged portion) extended or enlarged from the display area DA to the other non-display area NDA except the pad portion PA. Therefore, the planarization layer 113 may have a size relatively wider than that of the display area DA.

The planarization layer 113 according to one example may be formed to have a relatively thick thickness, thereby providing a flat surface on the display area DA and the non-display area NDA. For example, the planarization layer 113 may be made of an organic material such as photo acryl, benzocyclobutene, polyimide and fluorine resin.

On the other hand, an upper surface of the planarization layer 113 can be provided flatly. Accordingly, the anode electrode 114 on the planarization layer 113 can also be provided flatly, and the organic light emitting layer 116 and the cathode electrode 117 formed thereon can also be provided flatly. Since the anode electrode 114, the organic light emitting layer 116, the cathode electrode 117, that is, the light emitting element layer E is provided to be flat in the light emission area EA, a thickness of each of the anode electrode 114, the organic light emitting layer 116 and the cathode electrode 117 in the light emission area EA may be uniformly formed. Therefore, the organic light emitting layer 116 may be uniformly emitted without deviation in the light emission area EA.

The anode electrode 114 can be formed on the planarization layer 113. Although not shown, the anode electrode 114 may be connected to a drain electrode 112d or a source electrode 112c of the thin film transistor 112 through a contact hole passing through the planarization layer 113 and the passivation layer 111c. An edge portions on both sides of the anode electrode 114 may be covered by the bank 115. The anode electrode 114 may be made of at least one of a transparent metal material or a semi-transmissive metal material.

Because the display apparatus 100 according to an embodiment of the present disclosure is configured as the bottom emission type, the anode electrode 114 may be formed of a transparent conductive material (or TCO), such as indium tin oxide (ITO) or indium zinc oxide (IZO) capable of transmitting light, or a semi-transmissive conductive material such as magnesium (Mg), silver (Ag), or an alloy of Mg and Ag.

Meanwhile, the material constituting the anode electrode 114 may include MoTi. The anode electrode 114 may be a first electrode or a pixel electrode.

The bank 115 may be an area, which does not emit light, and can be placed adjacent to the light emission area EA of each of the plurality of sub-pixels SP. For example, the bank 115 may be disposed in the non-light emission area NEA. The bank 115 may be formed to cover a portion of the edge of the anode electrode 114. Accordingly, the bank 115 may prevent the anode electrode 114 and the cathode electrode 117 in the edge of the anode electrode 114. The exposed portion of the anode electrode 114 that is not covered by the bank 115 may be included in the light emitting portion (or light emission area EA).

After the bank 115 is formed, an organic light emitting layer 116 may be formed to cover the anode electrode 114 and the bank 115. Thus, the bank 115 may be partially provided between the anode electrode 114 and the organic light emitting layer 116. The bank 115 according to one example may comprise organic material and/or inorganic material.

The organic light emitting layer 116 may be formed on the anode electrode 114 and the bank 115. According to one example, the organic light emitting layer 116 may be disposed in the light emission area EA and the non-light emission area NEA. The organic light emitting layer 116 may be provided between the anode electrode 114 and the cathode electrode 117. Thus, when a voltage is applied to each of the anode electrode 114 and the cathode electrode 117, an electric field is formed between the anode electrode 114 and the cathode electrode 117. Therefore, the organic light emitting layer 116 may emit light. The organic light emitting layer 116 may be formed of a plurality of subpixels SP and a common layer provided on the bank 115.

The organic light emitting layer 116 according to one embodiment may be provided to emit white light. The organic light emitting layer 116 may include a plurality of stacks which emit lights of different colors. For example, the organic light emitting layer 116 may include a first stack, a second stack, and a charge generating layer (CGL) provided between the first stack and the second stack. The light emitting layer may be provided to emit the white light, and thus, each of the plurality of subpixels SP may include a color filter CF suitable for a corresponding color.

The first stack may be provided on the anode electrode 114 and may be implemented a structure where a hole injection layer (HIL), a hole transport layer (HTL), an emission layer (EML(B)), and an electron transport layer (ETL) are sequentially stacked.

The charge generating layer may supply an electric charge to the first stack and the second stack. The charge generating layer may include an N-type charge generating layer for supplying an electron to the first stack and a P-type charge generating layer for supplying a hole to the second stack. The N-type charge generating layer may include a metal material as a dopant.

The second stack may be provided on the first stack and may be implemented in a structure where a hole transport layer (HTL), a yellow-green (YG) emission layer (EML(YG)), and an electron injection layer (EIL) are sequentially stacked.

In the display apparatus 100 according to an embodiment of the present disclosure, because the organic light emitting layer 116 is provided as a common layer, the first stack, the charge generating layer, and the second stack may be arranged all over the plurality of subpixels SP. The organic light emitting layer 116, according to another example, may be provided in a three-stacked structure or a four-stacked structure, depending on the number of stacks stacked.

The cathode electrode 117 may be formed on the organic light emitting layer 116. The cathode electrode 117 may be arranged in a part of the non-display area NDA and the display area DA. In the display area DA, the cathode electrode 117 may be arranged in the light emission area EA and the non-light emission area NEA. That is, the cathode electrode 117 may be arranged to cover the entire display area DA. As a result, the cathode electrode 117 may be arranged to have a size larger than the display area DA and smaller than the substrate 110.

The cathode electrode 117 according to one example may include a metal material. The cathode electrode 117 may reflect the light emitted from the organic light emitting layer 116 in the plurality of subpixels SP toward a lower surface of the substrate 110. Therefore, the display apparatus 100 according to one embodiment of the present disclosure may be implemented as a bottom emission type display apparatus.

The display apparatus 100 according to one embodiment of the present disclosure is a bottom emission type and has to reflect light emitted from the organic light emitting layer 116 toward the substrate 110. Thus, the cathode electrode 117 may be made of a metal material having high reflectance. The cathode electrode 117 according to one example may be formed of a metal material having high reflectance such as a stacked structure (Ti/Al/Ti) of aluminum and titanium, a stacked structure (ITO/Al/ITO) of aluminum and ITO, an Ag alloy and a stacked structure (ITO/Ag alloy/ITO) of Ag alloy and ITO. The Ag alloy may be an alloy such as silver (Ag), palladium (Pd) and copper (Cu). The cathode electrode 117 may be expressed as terms such as a second electrode, an opposing electrode and a reflective electrode.

The encapsulation layer 118 is formed on the cathode electrode 117. The encapsulation layer 118 serves to prevent or at least reduce oxygen or moisture from penetrating into the organic light emitting layer 116 and the cathode electrode 117. To this end, the encapsulation layer 118 can be configured to include a getter capable of absorbing oxygen or moisture. Alternatively, the encapsulation layer 118 can comprise a plurality of layers including at least one inorganic film and at least one organic film.

On the other hand, as shown in FIG. 2, the encapsulation layer 118 can be disposed not only in the light emission area EA but also in the non-light emission area NEA. The encapsulation layer 118 can be disposed between the cathode electrodes 117 and the opposing substrate 200.

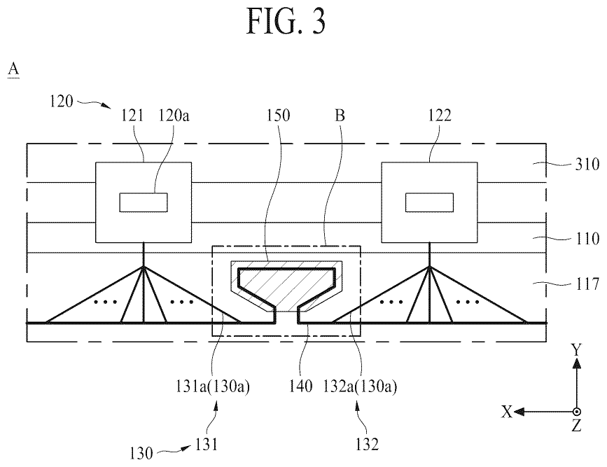

Hereinafter, the display apparatus 100 according to one embodiment of the present disclosure will be specifically described with reference to FIGS. 3 to 6.

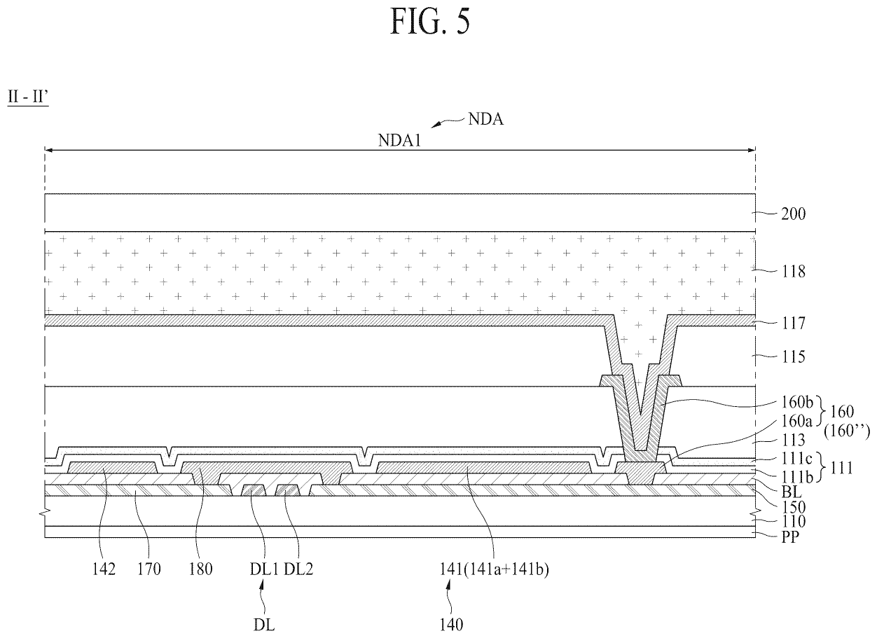

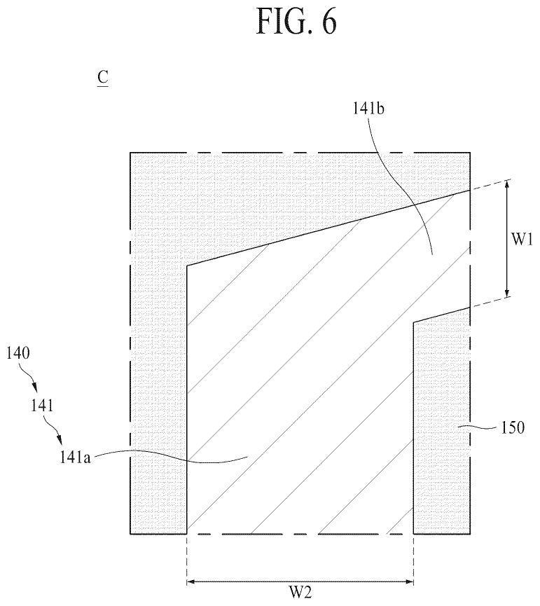

FIG. 3 is a schematic plan view of part A shown in FIG. 1 according to one embodiment of the present disclosure, FIG. 4 is a schematic enlarged view of part B shown in FIG. 3 according to one embodiment of the present disclosure, FIG. 5 is a schematic cross-sectional view of the line II-II′ shown in FIG. 4 according to one embodiment of the present disclosure, and FIG. 6 is a schematic enlarged view of part C shown in FIG. 4 according to one embodiment of the present disclosure.

Referring to FIG. 3, the heat path changing portion 150 may be placed between an outermost lines 130a connected to each of two different tabs. For example, the plurality of lines 130 may be connected to each of two different tabs. The outermost lines 130a may be lines placed at an outermost end of the plurality of lines 130.

For example, the plurality of tabs 120 may include a first tab 121 and a second tab 122. The plurality of lines 130 may be connected to each of the first tab 121 and the second tab 122. Here, among the plurality of lines 130 connected to the first tab 121, an outermost line may be the first outermost line 131a. Among the plurality of lines 130 connected to the second tab 122, an outermost line may be the second outermost line 132a. The plurality of lines 130 connected to each of the first tab 121 and the second tab 122 may be pixel power lines EVDD.

As shown in FIG. 3, the first tab 121 and the second tab 122 may be arranged adjacent to each other. Each of the first tab 121 and the second tab 122 may include the source drive IC 120a.

The plurality of lines 130 may include a plurality of first lines 131 connected to the first tab 121, and a plurality of second lines 132 connected to the second tab 122. As shown in FIG. 3, the plurality of first lines 131 may include a first outermost line 131a arranged closest to the plurality of second lines 132. The plurality of second lines 132 may include a second outermost line 132a arranged closest to the first outermost line 131a. The heat path changing portion 150 may be arranged between the first outermost line 131a and the second outermost line 132a.

As described above, the heat path changing portion 150 is positioned between the connecting line 140 and the polarizing plate PP (shown in FIG. 2) to change the path of heat traveling from the connecting line 140 to the polarizing plate PP. For example, the heat path changing portion 150 is provided to include a metal material and can receive heat emitted from the connecting line 140 and transfer it to the cathode electrode 117. Here, the fact that the heat path changing portion 150 receives heat from the connecting line 140 may mean that it is transferred by radiant heat. For example, as shown in FIG. 5, the heat path changing portion 150 is provided to overlap the connecting line 140 while not in contact with the connecting line 140 (or in a non-contact state), thereby allowing heat to be transferred from the connecting line 140.

Meanwhile, since the cathode electrode 117 is placed over the entire display area DA and a part of the non-display area NDA, its area is larger than that of the connecting line 140, and thus the heat dissipation efficiency can be increased. Accordingly, the display apparatus 100 according to one embodiment of the present disclosure can prevent the polarizing plate PP from melting or being damaged due to the heat of the connecting line 140 by allowing the heat path changing portion 150 to radiate (or disperse) the heat received from the connecting line 140 to the cathode electrode 117 having a large area.

In addition, the display apparatus 100 according to one embodiment of the present disclosure is provided so that heat of the connecting line 140 is radiated (or distributed) to the entire area of the display panel (or the cathode electrode 117) through the cathode electrode 117, so that a peak temperature of the display panel can be reduced, and thus not only a reliability can be improved but also a service life can be increased.

In addition, the display apparatus 100 according to one embodiment of the present disclosure is provided such that the heat path changing portion 150 is arranged between the first outermost line 131a and the second outermost line 132a, so that heat transferred to the heat path changing portion 150 can be prevented from being transferred to each of other lines (for example, the first outermost line 131a and the second outermost line 132a), so that the first outermost line 131a and the second outermost line 132a can be prevented from being damaged by heat. Meanwhile, as illustrated in FIG. 3, the space between the first outermost line 131a of the first tab 121 and the second outermost line 132a of the second tab 122 is provided in a trapezoidal shape (or an inverted trapezoidal shape or a hexagonal shape), so that the heat path changing portion 150 arranged between the first outermost line 131a and the second outermost line 132a can also be provided in a trapezoidal shape (or an inverted trapezoidal shape or a hexagonal shape).

In the display apparatus 100 according to one embodiment of the present disclosure, the connecting line 140 (or the plurality of connecting lines 140) may connect the plurality of lines 130. The connecting line 140 according to one example may be the pixel power shorting bar. The connecting line 140 according to one example is provided in a straight shape overall, but may be provided in a trapezoidal shape (or an inverted trapezoidal shape or a hexagonal shape) with one side open between the first outermost line 131a and the second outermost line 132a.

In the case of a general display apparatus, the connection line is provided in a straight form. For example, the connection line between the first outermost line and the second outermost line in FIG. 3 is provided in a straight form. Therefore, if there is a deviation in the power (or signal) applied to each of the first and second tabs, the current may be concentrated in the connecting line provided with the shortest length between the first outermost line and the second outermost line, which may aggravate heat generation, and this may cause the polarizing plate to melt.

In contrast, in the display apparatus 100 according to one embodiment of the present disclosure, the connecting line 140 between the first outermost line 131a and the second outermost line 132a is provided in the trapezoidal shape (or the inverted trapezoidal shape or a hexagonal shape) with one side open, so that a length of the connecting line 140 between the first outermost line 131a and the second outermost line 132a can be increased. Accordingly, the display apparatus 100 according to one embodiment of the present disclosure can prevent current from being concentrated in the connecting line 140 between the first outermost line 131a and the second outermost line 132a, thereby reducing heat generation in the connecting line 140.

In addition, in the display apparatus 100 according to one embodiment of the present disclosure, since the connecting line 140 between the first outermost line 131a and the second outermost line 132a is provided in the trapezoidal shape (or the inverted trapezoidal shape or the hexagonal shape) with one side open, the length (or cross-sectional area) of the connecting line 140 can be increased compared to the general display apparatus in which the connection line between the first outermost line and the second outermost line is provided in the straight shape, and as a result, the heat generation per area compared to the power (or signal) deviation of the first outermost line 131a and the second outermost line 132a can be reduced.

Additionally, in the display apparatus 100 according to one embodiment of the present disclosure, the connecting line 140 between the first outermost line 131a and the second outermost line 132a is provided in the trapezoidal shape (or the inverted trapezoidal shape or the hexagonal shape) with one side open, so that a location where heat is generated can be moved toward the pad portion PA, and thus the influence of heat on the pixel P of the display area DA can be minimized. Meanwhile, as illustrated in FIG. 1, the cathode electrode 117 may be provided in a form that extends to the entire display area DA and a portion of the non-display area NDA. Accordingly, the heat path changing portion 150 may partially overlap with the cathode electrode 117 in the non-display area NDA (or the first non-display area NDA1). In addition, since the heat path changing portion 150 is positioned between the first outermost line 131a and the second outermost line 132a, the heat path changing portion 150 may overlap a part of the connecting line 140. For example, the heat path changing portion 150 may overlap the portion of the connecting line 140 provided in the trapezoidal shape (or the inverted trapezoidal shape or the hexagonal shape) with one side open between the first outermost line 131a and the second outermost line 132a.

As a result, the display apparatus 100 according to one embodiment of the present disclosure may have a structural feature in which the heat path changing portion 150 partially overlaps each of the cathode electrode 117 and the connecting line 140.

In the above, the heat path changing portion 150 is described as being provided in the trapezoidal shape (or the inverted trapezoidal shape or a hexagonal shape), but is not limited thereto, and if it can be arranged between the first outermost line 131a and the second outermost line 132a, it may be provided in another shape similar to the trapezoidal shape (or the inverted trapezoidal shape or a hexagonal shape), for example, a pentagonal shape, an octagonal shape, etc.

Meanwhile, the inventor who developed the display apparatus 100 according to the present disclosure conducted research to prevent heat generation by cutting the connection line between the first outermost line and the second outermost line in order to solve the problem of increased heat generation that occurs in the case of the general display apparatus in which the connection line between the first outermost line and the second outermost line is provided in a straight shape. However, in this case, there is a problem that vertical line stains occur due to power (or signal) deviations between lines (e.g., pixel power lines) placed in the display area due to the power (or signal) deviations of different tabs.

Therefore, the display apparatus 100 according to one embodiment of the present disclosure is provided in a length-extended, the trapezoidal shape with one side open, so that the connecting line 140 between the first outermost line 131a and the second outermost line 132a is not disconnected, so that a current can be prevented from being concentrated in the connecting line 140 between the first outermost line 131a and the second outermost line 132a, and thus heat generation can be reduced. In addition, since the connecting line 140 between the first outermost line 131a and the second outermost line 132a does not need to be disconnected (or divided), vertical line stains can be improved or prevented.

Referring to FIG. 4, in the display apparatus 100 according to one embodiment of the present disclosure, the connecting line 140 may include a first connecting line 141 and a second connecting line 142.

The first connecting line 141 may be a line that overlaps the heat path changing portion 150. The second connecting line 142 may be a line that does not overlap (e.g., non-overlapping) the heat path changing portion 150. Accordingly, as shown in FIG. 4, the first connecting line 141 may not overlap the data line DL and/or the reference line RL. In contrast, the second connecting line 142 may overlap with the data line DL and/or the reference line RL. As illustrated in FIG. 4, most of the second connecting line 142 is arranged in the second direction (X-axis direction), and thus may partially overlap with the data line DL and/or the reference line RL arranged in the first direction (Y-axis direction).

The second connecting line 142 can be connected to the plurality of lines 130. The first connecting line 141 can be indirectly connected to the plurality of lines 130 through the second connecting line 142. As illustrated in FIG. 4, the connecting line 140 including the first connecting line 141 and the second connecting line 142 can be provided in an omega shape overall. Accordingly, based on FIG. 4, the first connecting line 141 may protrude upwardly relative to the second connecting line 142, and thus, the first connecting line 141 may overlap the heat path changing portion 150 positioned upwardly relative to the second connecting line 142.

Referring to FIG. 5, the heat path changing portion 150 may be placed between the polarizing plate PP and the connecting line 140. According to one example, the heat path changing portion 150 may be placed between the polarizing plate PP and the first connecting line 141. The heat path changing portion 150 may be placed spaced apart from the first connecting line 141 by the thickness of the buffer layer BL. Accordingly, heat generated from the first connecting line 141 and directed toward the polarizing plate PP can be blocked by the heat path changing portion 150. In addition, a temperature of the heat path changing portion 150 can rise due to a heat of the first connecting line 141. This is because the heat path changing portion 150 is made of a metal material and is positioned close to the first connecting line 141.

As a result, the heat generated in the first connecting line 141 can be transferred to the heat path changing portion 150, and the heat transferred to the heat path changing portion 150 can be transferred to the cathode electrode 117 connected to (or in contact with) the heat path changing portion 150. The heat transferred to the cathode electrode 117 can be dissipated (or dispersed) to the cathode electrode 117 which has a wider area than the connecting line 140, so that the heat generation per unit area can be reduced. Therefore, the display apparatus 100 according to one embodiment of the present disclosure is equipped so that heat generation of the connecting line 140 is dissipated (or dispersed) through the heat path changing portion 150 and the cathode electrode 117, thereby preventing or at least reducing a likelihood of melting of the polarizing plate PP.

Referring to FIG. 5, a display apparatus 100 according to one embodiment of the present disclosure may further include a plurality of contact portions 160 connecting the heat path change portion 150 and the cathode electrode 117.

As illustrated in FIG. 5, the cathode electrode 117 and the heat path changing portion 150 may be placed on different layers. For example, the cathode electrode 117 may be placed on the bank 115, and the heat path changing portion 150 may be placed between the buffer layer BL and the substrate 110. Therefore, in order to transfer the heat transferred to the heat path changing portion 150 to the cathode electrode 117, the heat path changing portion 150 and the cathode electrode 117 must be connected. In the display apparatus 100 according to one embodiment of the present disclosure, the heat path changing portion 150 may be connected to the cathode electrode 117 through the plurality of contact portions 160. Each of the plurality of contact portions 160 may be formed of a metal material (or a material having high thermal conductivity) to transfer heat of the heat path changing portion 150 to the cathode electrode 117.

Each of the plurality of contact portions 160 according to an example may include a first metal layer 160a and a second metal layer 160b.

The first metal layer 160a may be arranged on a same layer as the connecting line 140. The first metal layer 160a may be formed together with the connecting line 140 when it is formed, so that it may be arranged on the same layer as the connecting line 140. For example, the first metal layer 160a may be arranged between the buffer layer BL and the interlayer insulating layer 111b. This first metal layer 160a may be in contact with the heat path changing portion 150. For example, a lower surface of the first metal layer 160a may be in contact with an upper surface of the heat path changing portion 150. An upper surface of the first metal layer 160a may be in contact with the second metal layer 160b. Meanwhile, the first metal layer 160a may be arranged to be spaced apart from the connecting line 140. Since the connecting line 140 is connected to the plurality of lines 130 that apply pixel power, and the first metal layer 160a is connected to the cathode electrode 117, if the connecting line 140 and the first metal layer 160a are electrically connected, a short circuit may occur. Accordingly, the display apparatus 100 according to one embodiment of the present disclosure may have a structural feature in which the first metal layer 160a is arranged spaced apart from the connecting line 140.

The second metal layer 160b can be in contact with each of the first metal layer 160a and the cathode electrode 117 between the first metal layer 160a and the cathode electrode 117. For example, the second metal layer 160b may be disposed on the planarization layer 113 and may be in contact with the first metal layer 160a through a contact hole penetrating the planarization layer 113, the passivation layer 111c, and the interlayer insulating layer 111b. The cathode electrode 117 may be disposed on the bank 115 and may be in contact with the second metal layer 160b through a contact hole penetrating the bank 115.

Therefore, the heat generated in the connecting line 140 is primarily transferred to the heat path changing portion 150 positioned apart from the connecting line 140, the heat transferred to the heat path changing portion 150 is secondarily transferred to the first metal layer 160a and the second metal layer 160b, and the heat transferred to the second metal layer 160b can be finally transferred to the cathode electrode 117. Accordingly, the display apparatus 100 according to one embodiment of the present disclosure can dissipate (or disperse) heat generated in the connecting line 140 through the heat path changing portion 150, the contact portion 160, and the cathode electrode 117, so that melting of the polarizing plate PP disposed below the heat path changing portion 150 can be prevented.

Referring again to FIG. 4, in a display apparatus 100 according to one embodiment of the present disclosure, the plurality of contact portions 160 may include a first contact portion 161.

The first contact portion 161 may be placed between the first connecting line 141 and the edge of the heat path changing portion 150. Here, the edge of the heat path changing portion 150 may mean an end of the heat path changing portion 150. Accordingly, as shown in FIG. 4, the first contact portion 161 can be arranged to partially surround the first connecting line 141. Accordingly, the first contact portion 161 can prevent heat generated from the first connecting line 141 from spreading to an outside of the heat path change portion 150. Therefore, the display apparatus 100 according to one embodiment of the present disclosure can prevent the plurality of lines 130 from being damaged by heat.

The first contact portion 161 is arranged on an outside of the first connecting line 141, and thus may be expressed in terms of an outer heat blocking barrier (or a first heat blocking barrier or a first wall structure). The cross-sectional structure of the first contact portion 161 is a same as the structure of the contact portion 160 described in FIG. 5, and therefore, a description thereof is omitted. Meanwhile, the first contact portion 161 may be provided in a form in which one side is open. That is, the first contact portion 161 may not be in a sealed form (or closed form). As described above, in order to reduce heat generation, the connecting line 140 may be provided in an omega form with a length extended in the upper direction of FIG. 4. Accordingly, the first contact portion 161 may be provided in a form with one side open so as not to interfere with (or come into contact with) the first connecting line 141 provided in an omega shape.

In the display apparatus 100 according to one embodiment of the present disclosure, the plurality of contact portions 160 may further include a second contact portion 162.

The second contact portion 162 may be partially arranged on an inner side of the first connecting line 141. According to one example, the second contact portion 162 may be formed along a shape of the first connecting line 141 while being spaced apart from the first connecting line 141 by a predetermined distance. Therefore, as shown in FIG. 4, the first connecting line 141 may be partially placed between the first contact portion 161 and the second contact portion 162. The cross-sectional structure of the second contact portion 162 may be a same as a structure of the contact portion 160 described in FIG. 5. Accordingly, in the display apparatus 100 according to one embodiment of the present disclosure, heat generated in the first connecting line 141 can be transferred (or dispersed) to the cathode electrode 117 not only through the first contact portion 161 but also through the second contact portion 162, so that the melting prevention effect of the polarizing plate PP can be further improved. Since the second contact portion 162 is arranged on the inner side of the first connecting line 141, it can be expressed in terms of an inner heat blocking barrier (or a second heat blocking barrier or a second wall structure).

Meanwhile, the second contact portion 162 may be provided in a sealed form (or closed form). This is to maximize the transfer of heat generated from the first connecting line 141 without the second contact portion 162 coming into contact with the first connecting line 141. That is, the second contact portion 162 may be provided in the sealed form (or closed form) to expand an area facing the first connecting line 141. Accordingly, as shown in FIG. 4, the second contact portion 162 can be formed along a shape of the first connecting line 141 at a location spaced apart from the first connecting line 141, and as a result, the second contact portion 162 can receive most of the heat generated in the first connecting line 141. The second contact portion 162 can transfer heat received from the first connecting line 141 to the cathode electrode 117. Therefore, the display apparatus 100 according to one embodiment of the present disclosure can improve the heat dissipation effect even through the second contact portion 162, so that melting of the polarizing plate can be prevented more effectively.

The first contact portion 161 and the second contact portion 162 can be placed on the heat path changing portion 150. That is, the first contact portion 161 and the second contact portion 162 can be placed to overlap the heat path changing portion 150. Accordingly, each of the first contact portion 161 and the second contact portion 162 can transfer heat transferred from the connecting line 140 to the heat path changing portion 150 to the cathode electrode 117.

If the first contact portion 161 and/or the second contact portion 162 are positioned apart from the heat path changing portion 150, the heat transfer efficiency to the cathode electrode 117 may be reduced. Therefore, the display apparatus 100 according to one embodiment of the present disclosure can minimize the reduction in heat transfer efficiency to the cathode electrode 117 by having the first contact portion 161 and the second contact portion 162 disposed on the heat path changing portion 150, thereby maximizing the heat dissipation effect.

Referring again to FIG. 4, in the display apparatus 100 according to one embodiment of the present disclosure, the plurality of contact portions 160 may further include a third contact portion 163 and a fourth contact portion 164.

The third contact portion 163 may be arranged on an inner side of the second contact portion 162. According to one example, at least one third contact portion 163 may be provided. For example, as shown in FIG. 4, the third contact portion 163 may be provided in plurality of numbers, and the plurality of third contact portions 163 may be arranged spaced apart from each other on the inside of the second contact portion 162. The third contact portions 163 can be provided in at least one of a dot shape, a rectangle shape, and a square shape. Accordingly, the plurality of third contact portions 163 can be easily provided on the inner side of the second contact portion 162 without interfering with each other.

Therefore, the display apparatus 100 according to one embodiment of the present disclosure is provided to further include at least one third contact portion 163 on the inner side of the second contact portion 162, so that a contact area between the heat path change portion 150 and the cathode electrode 117 can be further increased, and thus the heat dissipation effect can be further improved.

The fourth contact portion 164 may be arranged on an outside of the first contact portion 161. According to one example, at least one fourth contact portion 164 may be provided. For example, as shown in FIG. 4, the fourth contact portion 164 may be provided in plurality of numbers, and the plurality of fourth contact portions 164 may be arranged spaced apart from each other on the outside of the first contact portion 161. For example, the plurality of fourth contact portions 164 may be arranged on a left side and a right side of the first contact portion 161 based on FIG. 4. The fourth contact portions 164 may be provided in at least one of a dot shape, a rectangle shape, and a square shape. Accordingly, the plurality of fourth contact portions 164 may be easily provided on the outside of the first contact portion 161 without interfering with each other.

Therefore, the display apparatus 100 according to one embodiment of the present disclosure is provided to further include at least one fourth contact portion 164 on the outer side of the first contact portion 161, so that a contact area between the heat path change portion 150 and the cathode electrode 117 can be maximized, and thus the heat dissipation effect can be maximized.

In the above, it has been described that the third contact portion 163 and/or the fourth contact portion 164 are provided in at least one of the dot shape, the rectangle shape, and the square shape, but this is not limited thereto and may be provided in other shapes as long as the contact area between the heat path change portion 150 and the cathode electrode 117 can be increased.

Referring to FIG. 4, the display apparatus 100 according to one embodiment of the present disclosure may further include at least one sub-heat path changing portion 170 partially overlapping with the second connecting line 142.

The sub-heat path changing portion 170 is for dissipating heat generated from the second connecting line 142. To this end, the sub-heat path changing portion 170 may be made of a metal material (or a material with high thermal conductivity). As shown in FIG. 4, each of the plurality of sub-heat path changing portion 170 is provided in a long rectangular shape in the first direction (Y-axis direction), so that it can partially overlap with the second connecting line 142 arranged in the second direction (X-axis direction). And, as shown in FIG. 5, the sub-heat path changing portion 170 can be placed below the second connecting line 142. Therefore, each of the plurality of sub-heat path changing portions 170 can block heat diffusing from the second connecting line 142 toward the polarizing plate PP, thereby preventing the polarizing plate PP from melting. In addition, each of the plurality of sub-heat path change portions 170 is provided to be in contact with a heat transfer portion 180, so that heat received from the second connecting line 142 can be transferred to the heat transfer portion 180.

Meanwhile, as shown in FIG. 4, each of the plurality of sub-heat path changing portion 170 may be arranged so as not to overlap with the data line DL and/or the reference line RL. As shown in FIG. 5, this is because the plurality of sub-heat path changing portion 170 are arranged on a same layer as the data line DL and/or the reference line RL. Accordingly, the display apparatus 100 according to one embodiment of the present disclosure may have a structural feature in which at least one sub-heat path changing portion 170 is positioned so as not to overlap with the data line DL and/or the reference line RL.

Referring to FIGS. 4 and 5, the display apparatus 100 according to one embodiment of the present disclosure may further include a heat transfer portion 180 that connects at least one sub-heat path changing portion 170 and a heat path changing portion 150.

The heat transfer portion 180 is for transferring heat transferred to at least one sub-heat path changing portion 170 to the heat path changing portion 150. To this end, the heat transfer portion 180 may be formed of a metal material (or a material with high thermal conductivity). As shown in FIG. 5, the heat transfer portion 180 may be placed on a same layer as the connecting line 140. The heat transfer portion 180 may be formed together with the connecting line 140 when it is formed, so that it may be placed on the same layer as the connecting line 140. For example, the heat transfer portion 180 may be placed between the buffer layer BL and the interlayer insulating layer 111b. One side of the heat transfer portion 180 can be in contact with the sub heat path changing portion 170 through a contact hole formed on the sub heat path changing portion 170. The other side of the heat transfer portion 180 can be in contact with the heat path changing portion 150 through a contact hole formed on the heat path changing portion 150. Accordingly, the heat transfer portion 180 can transfer the heat transferred to at least one sub-heat path changing portion 170 to the heat path changing portion 150. The heat transferred to the heat path changing portion 150 can be transferred to the cathode electrode 117 through the contact portion 160 and can be radiated (or dispersed) through the cathode electrode 117.

Therefore, the display apparatus 100 according to one embodiment of the present disclosure can prevent or at least reduce the likelihood of melting of the polarizing plate PP by dissipating (or dispersing) heat generated from each of the first connecting line 141 and the second connecting line 142 to the cathode electrode 117 through the sub-heat path changing portion 170 and the heat path changing portion 150, and the lifespan can be improved due to the prevention of melting of the polarizing plate PP, so that low-power operation is possible compared to an entire lifespan, so that power consumption can be reduced. Meanwhile, as shown in FIG. 4, one side of each of the plurality of sub-heat path changing portions 170 is connected to (or in contact with) the heat transfer portion 180 arranged in the second direction (X-axis direction), so that it can be provided as a rake-shaped iron line structure.

Referring to FIG. 5, at least one sub-heat path changing portion 170 is provided on the same layer as the plurality of data lines DL, so that it may not overlap with the plurality of data lines DL. In addition, as shown in FIG. 5, the heat path changing portion 150 may also be provided on the same layer as the plurality of data lines DL. Accordingly, the display apparatus 100 according to one embodiment of the present disclosure may have a structural feature in which the data line DL is arranged between at least one sub-heat path changing portion 170 and a heat path changing portion 150. In this case, as shown in FIG. 5, the heat transfer portion 180 may partially overlap with the data line DL. However, it is not limited thereto, and as shown in FIG. 4, some of the data lines among the plurality of data lines DL may be placed between the plurality of sub-heat path changing portions 170.

Referring again to FIG. 4, in the display apparatus 100 according to one embodiment of the present disclosure, the first connecting line 141 may include a first sub-connecting line 141a and a second sub-connecting line 141b.

The first sub-connecting line 141a can be connected to the second connecting line 142. The second sub-connecting line 141b can be connected to the first sub-connecting line 141a. Therefore, the first sub-connecting line 141a can be arranged closer to an edge of the heat path changing portion 150 than the second sub-connecting line 141b.

As illustrated in FIG. 4, the first sub-connecting line 141a may be arranged between the second sub-connecting line 141b and the second connecting line 142. In addition, the second sub-connecting line 141b may be arranged to surround most of the second contact portion 162 while being connected to the first sub-connecting line 141a. Accordingly, most of the second sub-connecting line 141b may be surrounded by the first contact portion 161.

Since the second sub-connecting line 141b is surrounded by the first contact portion 161 while surrounding most of the second contact portion 162, most of the second sub-connecting line 141b can be placed between the first contact portion 161 (or the outer heat blocking barrier) and the second contact portion 162 (or the inner heat blocking barrier), as shown in FIG. 4. Accordingly, the display apparatus 100 according to one embodiment of the present disclosure can prevent heat generated in the second sub-connecting line 141b from spreading to other lines adjacent to the heat path changing portion 150 by having the first contact portion 161 and the second contact portion 162 arranged to surround the inner and outer sides of the second sub-connecting line 141b. In addition, in the display apparatus 100 according to one embodiment of the present disclosure, the first contact portion 161 and the second contact portion 162 are arranged to surround the inner and outer sides of the second sub-connecting line 141b, so that heat generated in the second sub-connecting line 141b can be additionally transferred (e.g., non-contact transferred) to the first contact portion 161 and the second contact portion 162, and thus the heat dissipation effect through the cathode electrode 117 can be maximized.

Referring to FIG. 4 and FIG. 6, in the display apparatus 100 according to one embodiment of the present disclosure, a width W1 of the second sub-connecting line 141b may be provided to be narrower than a width W2 of the first sub-connecting line 141a. When the width W1 of the second sub-connecting line 141b is less than the width W2 of the first sub-connecting line 141a, the current density in the second sub-connecting line 141b can increase more than that in the first sub-connecting line 141a. Accordingly, the second sub-connecting line 141b may generate more heat than the first sub-connecting line 141a. As described above, most of the second sub-connecting line 141b may be placed between the first contact portion 161 (or the outer heat blocking barrier) and the second contact portion 162 (or the inner heat blocking barrier). Accordingly, even if the heat generation of the second sub-connecting line 141b increases more than that of the first sub-connecting line 141a, the heat dissipation effect through the cathode electrode 117 can be improved because the first contact portion 161 and the second contact portion 162 can receive heat from the inner and outer sides of the second sub-connecting line 141b, respectively.

As a result, in the display apparatus 100 according to one embodiment of the present disclosure, the width W1 of the second sub-connecting line 141b is provided to be narrower than the width W2 of the first sub-connecting line 141a, so that heat generated in the connecting line 140 can be induced to the second sub-connecting line 141b, and a heat induced to the second sub-connecting line 141b can be dissipated to the cathode electrode 117 through the first contact portion 161 and the second contact portion 162 arranged on the inner and outer sides of the second sub-connecting line 141b. Therefore, in the display apparatus 100 according to one embodiment of the present disclosure, melting prevention of the polarizing plate PP can be maximized.

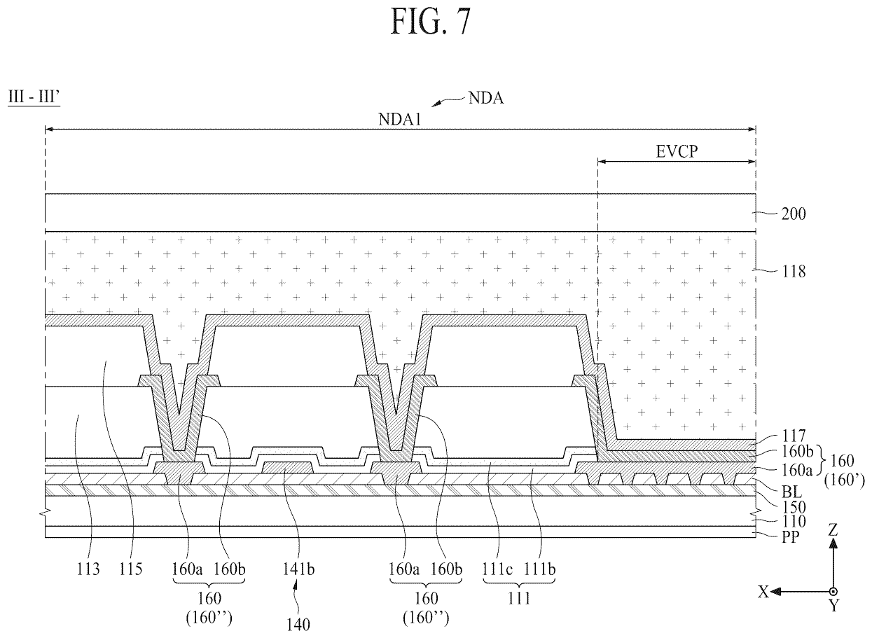

FIG. 7 is a schematic cross-sectional view of the line II-III′ shown in FIG. 4 according to one embodiment of the present disclosure.

Referring to FIG. 7, the display apparatus 100 according to one embodiment of the present disclosure may further include a common power contact portion EVCP.

The common power contact portion EVCP is for applying common power applied from the pad portion PA to the cathode electrode 117. For example, as shown in FIG. 7, the common power contact portion EVCP can transmit common power applied to the heat path changing portion 150 to the cathode electrode 117 through the contact portion 160.

As shown in FIG. 4, the common power contact portion EVCP may be positioned higher in the first direction (Y-axis direction) than the first contact part 161. Accordingly, the common power contact portion EVCP may be provided closer to the pad portion PA than the first contact part 161. The heat path changing portion 150 can be formed by extending from the heat transfer portion 180 in the first direction (Y-axis direction) to the common power contact portion EVCP. Accordingly, the heat path changing portion 150 can be connected to the cathode electrode 117 through the contact portion 160 at the common power contact portion EVCP.

Meanwhile, a part of the heat path changing portion 150 arranged in the common power contact portion EVCP may be connected to a common power line of the pad portion PA. Accordingly, the heat path changing portion 150 may function as a line that applies common power. As shown in FIG. 7, the heat path changing portion 150 can be connected to the cathode electrode 117 through the first metal layer 160a and the second metal layer 160b in the common power contact portion EVCP. Therefore, the common power applied to the heat path changing portion 150 can be applied to the cathode electrode 117 through the first metal layer 160a and the second metal layer 160b.

As shown in FIG. 7, an area where the second metal layer 160b and the cathode electrode 117 come into contact in the common power contact portion EVCP may be larger than an area where the second metal layer 160b and the cathode electrode 117 come into contact in an area adjacent to the common power contact portion EVCP (e.g., an area adjacent to a left side of the common power contact portion EVCP based on FIG. 7). Accordingly, most of the common power applied from the pad portion PA may be applied from the common power contact portion EVCP to the cathode electrode 117.

As a result, the common power contact portion EVCP can apply most of the common power to the cathode electrode 117 through the heat path changing portion 150 and the contact portion 160, and thus can be expressed in terms of a common power supply portion. In addition, the contact portion 160 provided in the common power contact portion EVCP has a function of transmitting common power, and thus can be expressed in terms of a common power transfer portion 160′.

Meanwhile, the heat path changing portion 150 may be formed to extend from the heat transfer portion 180 in the first direction (Y-axis direction) to the common power contact portion EVCP. Accordingly, the heat path changing portion 150 located between the common power contact portion EVCP and the heat transfer portion 180 in the first direction (Y-axis direction) may be connected to the cathode electrode 117 through the plurality of contact portions 160.

For example, based on FIG. 7, the heat path changing portion 150 extended to the left of a common power contact portion EVCP may be connected to the cathode electrode 117 through the plurality of contact portions 160. This structure may be expressed in terms of a heat dissipation portion since it transfers heat from the heat path changing portion 150 to the cathode electrode 117 through the plurality of contact portions 160.

Meanwhile, the plurality of contact portions 160 arranged on a left side of the common power contact portion EVCP in FIG. 7 have the function of transferring the heat of the heat path changing portion 150 to the cathode electrode 117, and thus can be expressed in terms of a heat path transfer portion 160″. In addition, the connection structure of the heat path changing portion 150, the contact portion 160, and the cathode electrode 117 on a right side of FIG. 5 may also be included in the heat dissipation portion. Accordingly, the contact portion 160 connecting the heat path changing portion 150 and the cathode electrode 117 on the right side of FIG. 5 may also be included in the heat path transfer portion 160″.

As illustrated in FIG. 4, the plurality of contact parts 160 (e.g., a first contact portion 161, a second contact portion 162, a third contact portion 163, and a fourth contact portion 164) may be provided on the heat path changing portion 150 located below the common power contact portion EVCP. The plurality of contact portions 160 (e.g., the first contact portion 161, the second contact portion 162, the third contact portion 163, and the fourth contact portion 164) may be the heat path transfer portions 160″ included in the heat dissipation portion, as they transfer heat from the heat path changing portion 150 to the cathode electrode 117.

Therefore, the display apparatus 100 according to one embodiment of the present disclosure can apply most of the common power to the cathode electrode 117 through the common power transfer portion 160′ from the common power contact portion EVCP, and can transfer heat to the cathode electrode 117 through the plurality of heat path transfer portions 160″ in an area other than the common power contact portion EVCP (e.g., an area below the common power contact portion EVCP with reference to FIG. 4). Therefore, the display apparatus 100 according to one embodiment of the present disclosure can implement a heat dissipation structure through the cathode electrode 117 while applying a common power to the cathode electrode 117.

Meanwhile, as shown in FIG. 7, the structure of each of the plurality of heat dissipating portions in the area other than the common power contact portion EVCP (e.g., the area below the common power contact portion EVCP based on FIG. 4) is identical to a structure of the common power supply portion in the common power contact portion EVCP, so that the common power can be applied to the cathode electrode 117 through the plurality of heat dissipating portions.

In the above, the first contact portion 161, the second contact portion 162, the third contact portion 163, and the fourth contact portion 164 are all described as functioning as heat dissipation parts, but the present invention is not limited thereto.

According to one embodiment of the present disclosure, the display apparatus 100 may use the first contact portion 161, the second contact portion 162, the third contact portion 163, and the fourth contact portion 164 as a heat dissipation portion and/or a common power supply portion, as needed.

For example, the first contact portion 161 and the second contact portion 162 can be used as the heat dissipation portion, and the third contact part 163 and the fourth contact part 164 can be used as the common power supply portion.

Alternatively, the first contact portion 161, the second contact portion 162, and the third contact portion 163 may be used as the heat dissipation portion, and the fourth contact portion 164 may be used as the common power supply portion.

Alternatively, the first contact portion 161, the second contact portion 162, and the fourth contact portion 164 may be used as the heat dissipation portion, and the third contact portion 163 may be used as the common power supply portion.

In this way, in the display apparatus 100 according to one embodiment of the present disclosure, when a heat dissipation function is more necessary than a common power supply, most of the plurality of contact portions 160 can be used as the heat dissipation portion, and in the opposite case, most of the plurality of contact portions 160 can be used as the common power supply portion.

For example, if a heat dissipation function is further required, most of the plurality of contact portions 160 may be densely arranged around the first connecting line 141. In contrast, if a common power supply function is further required, most of the plurality of contact portions 160 may be densely arranged around the common power contact portion EVCP.

As a result, the display apparatus 100 according to one embodiment of the present disclosure can maximize the heat dissipation function using the cathode electrode 117 through the arrangement of the plurality of contact portions 160 on the heat path changing portion 150. Alternatively, the display apparatus 100 according to one embodiment of the present disclosure can prevent a common power drop applied to the cathode electrode 117 through the arrangement of the plurality of contact portions 160 on the heat path changing portion 150.

Embodiments of the present disclosure have been described in more detail with reference to the accompanying drawings, but the present disclosure is not necessarily limited to these embodiments and may be practiced in various modifications without departing from the technical ideas of the present disclosure. Accordingly, the embodiments disclosed herein are intended to illustrate, not limit, the technical ideas of the present disclosure, and the scope of the technical ideas of the present disclosure is not limited by these embodiments. Therefore, the embodiments described above are exemplary in all respects and should be understood as non-limiting. All technical ideas within the scope of protection of this disclosure shall be construed to be included within the scope of the claims of this disclosure.

The display apparatus according to the present disclosure is provided so that heating of the connecting line is dispersed through the cathode electrode, thereby preventing melting of the polarizing plate.

The display apparatus according to the present disclosure is provided so that heating is dispersed through the cathode electrode, so that the peak temperature of the display panel can be reduced.

Since the display apparatus according to the present disclosure does not require the connecting line to be split (or disconnected), the vertical line staining can be prevented.

The display apparatus according to the present disclosure can have an improved lifespan due to prevention of melting of the polarizing plate, and thus can be driven at low power compared to the entire lifespan, thereby reducing power consumption.

The effects to be obtained from the present disclosure are not limited to those mentioned above, and other effects not mentioned will be apparent to one of ordinary skill in the art from the description.

What is claimed is:

1. A display apparatus comprising:
a substrate having a display area in which a plurality of sub-pixels are arranged and a non-display area around the display area;
a plurality of lines in the non-display area of the substrate, the plurality of lines connected to each of a plurality of tabs;
a connecting line connecting the plurality of lines;
a heat path changing portion partially overlapping the connecting line; and
a cathode electrode in the display area and a portion of the non-display area,
wherein the heat path changing portion is connected to the cathode electrode.

2. The display apparatus of claim 1, further comprising:
a polarizing plate below the substrate, and
wherein the heat path changing portion is between the polarizing plate and the connecting line.

3. The display apparatus of claim 1, wherein the heat path changing portion is partially overlapped with each of the cathode electrode and the connecting line.

4. The display apparatus of claim 1, wherein the heat path changing portion is between outermost lines among the plurality of lines connected to each of two different tabs among the plurality of tabs.

5. The display apparatus of claim 1, wherein the plurality of tabs include a first tab and a second tab that are adjacent to each other,
wherein the plurality of lines include a plurality of first lines connected to the first tab and a plurality of second lines connected to the second tab,
wherein the plurality of first lines include a first outermost line that is closest to the plurality of second lines,
wherein the plurality of second lines include a second outermost line that is closest to the first outermost line, and
wherein the heat path changing portion is between the first outermost line and the second outermost line.

6. The display apparatus of claim 1, wherein the heat path changing portion comprises a metal material.

7. The display apparatus of claim 1, wherein the heat path changing portion has a trapezoidal shape.

8. The display apparatus of claim 1, wherein the connecting line includes a first connecting line and a second connecting line connected to the first connecting line,
wherein the first connecting line overlaps the heat path changing portion and the second connecting line is non-overlapping with the heat path changing portion.

9. The display apparatus of claim 8, further comprising:
a plurality of contact portions connecting the heat path changing portion and the cathode electrode.

10. The display apparatus of claim 9, wherein each of the plurality of contact portions comprises:
a first metal layer on a same layer as the connecting line, the first metal layer in contact with the heat path changing portion; and
a second metal layer between the first metal layer and the cathode electrode, the second metal layer in contact with each of the first metal layer and the cathode electrode.

11. The display apparatus of claim 9, wherein the plurality of contact portions include a first contact portion between the first connecting line and an edge of the heat path changing portion, and the first contact portion partially surrounds the first connecting line.

12. The display apparatus of claim 11, wherein the plurality of contact portions further include a second contact portion partially on an inner side of the first connecting line and the first connecting line is partially between the first contact portion and the second contact portion.

13. The display apparatus of claim 12, wherein the second contact portion is provided in a closed form.

14. The display apparatus of claim 12, wherein the first contact portion and the second contact portion are on the heat path changing portion.

15. The display apparatus of claim 12, wherein the plurality of contact portions further comprise:
at least one third contact portion on an inner side of the second contact portion; and
at least one fourth contact portion on an outer side of the first contact portion.

16. The display apparatus of claim 15, wherein the at least one third contact portion has at least one of a dot shape and a square shape.

17. The display apparatus of claim 8, further comprising:
at least one sub-heat path changing portion partially overlapping the second connecting line.

18. The display apparatus of claim 16, further comprising:
a heat transfer portion connecting the at least one sub-heat path changing portion and the heat path changing portion.

19. The display apparatus of claim 18, wherein the heat transfer portion is on a same layer as the connecting line.

20. The display apparatus of claim 17, further comprising:
a data line that supplies a driving signal to each of the plurality of sub-pixels, the data line between the at least one sub-heat path changing portion and the heat path changing portion.

21. The display apparatus of claim 9, wherein the first connecting line comprises:
a first sub-connecting line connected to the second connecting line; and
a second sub-connecting line connected to the first sub-connecting line,
wherein a width of the second sub-connecting line is less than a width of the first sub-connecting line.

22. The display apparatus of claim 21, wherein the plurality of contact portions include a first contact portion between the first connecting line and an edge of the heat path changing portion and most of the second sub-connecting line is surrounded by the first contact portion.
